(19) United States
(12) Patent Application Publication
(10) Pub. No.: US 2023/0270005 A1
(43) Pub. Date: Aug. 24, 2023

(54) COMPOUND FOR ORGANIC OPTOELECTRONIC DEVICE AND OPTOELECTRONIC DEVICE INCLUDING THE SAME

(71) Applicant: UNIVERSITY-INDUSTRY COOPERATION GROUP OF KYUNG HEE UNIVERSITY, Yongin-si (KR)

(72) Inventors: Jongwook PARK, Seoul (KR); Seokwoo KANG, Hwaseong-si (KR)

(21) Appl. No.: 18/108,142

(22) Filed: Feb. 10, 2023

(30) Foreign Application Priority Data
Feb. 24, 2022 (KR) 10-2022-0024230

(51) Int. Cl. H10K 85/60; C07F 5/02; C09K 11/06

(52) U.S. Cl. CPC H10K 85/658; C07F 5/027; C09K 11/06; C09K 2211/1007; H10K 50/11

(57) ABSTRACT

Provided are a compound for an organic optoelectronic device represented by Chemical Formula 1 and an optoelectronic device including the same.

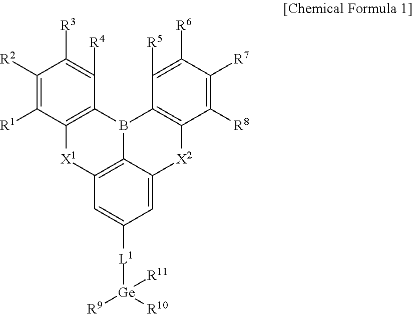

(The definition of Chemical Formula 1 is as described in the detailed description.)

### CROSS-REFERENCE TO RELATED APPLICATION

This application claims priority to and the benefit of Korean Patent Application No. 10-2022-0024230 filed in the Korean Intellectual Property Office on Feb. 24, 2022, the entire contents of which are incorporated herein by reference.

### BACKGROUND OF THE INVENTION

### (a) Field of the Invention

The present invention relates to a compound for an organic optoelectronic device and an optoelectronic device including the same.

### (b) Description of the Related Art

An organic optoelectronic device is a device that converts electrical energy into photoenergy, and vice versa.

Organic optoelectronic devices may be classified as follows in accordance with their driving principles. One is a photoelectric device where excitons generated by photoenergy are separated into electrons and holes and the electrons and holes are transferred to different electrodes respectively and electrical energy is generated, and the other is a light emitting device to generate photoenergy from electrical energy by supplying a voltage or a current to electrodes.

Examples of the organic optoelectronic device include an organic photoelectric device, an organic light emitting diode, and a solar cell.

Among them, organic light emitting diodes (OLEDs) have recently been attracting great attention due to an increase in demand for flat panel display devices. The organic light emitting diode converts electrical energy into light by applying current to an organic light emitting material, and generally has a structure in which an organic layer or an inorganic layer is disposed as a light emitting layer between an anode and a cathode.

On the other hand, in the case of the existing blue organic light emitting diode, it is difficult to inject holes and electrons due to a wide bandgap inherent in the material, and thus the luminous efficiency and life-span are significantly low.

### SUMMARY OF THE INVENTION

An embodiment provides a new blue organic light emitting material (compound for an organic optoelectronic device) having excellent optical characteristics.

Another embodiment provides an optoelectronic device including the compound for the organic optoelectronic device.

According to an embodiment, a compound for an organic optoelectronic device represented by Chemical Formula 1 is provided.

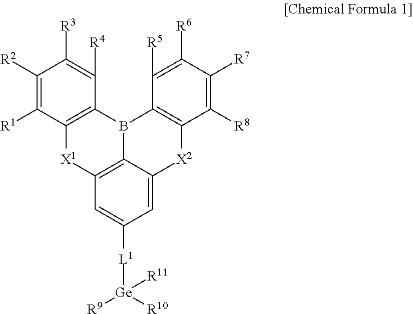

In Chemical Formula 1,

X¹ and X² are each independently an oxygen atom or a sulfur atom,

L¹ is a single bond, a substituted or unsubstituted C1 to C20 alkylene group, or a substituted or unsubstituted C6 to C20 arylene group, and

R¹ to R¹¹ are each independently a hydrogen atom, a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C20 aryl group, or a substituted or unsubstituted C2 to C20 heterocyclic group.

X¹ and X² may each independently be an oxygen atom.

L¹ may be a substituted or unsubstituted C6 to C20 arylene group.

At least one of R¹ to R⁴ may be a substituted or unsubstituted C1 to C20 alkyl group, and at least one of R⁵ to R⁸ may be a substituted or unsubstituted C1 to C20 alkyl group.

R⁹ to R¹¹ may each independently be a substituted or unsubstituted C6 to C20 aryl group.

The compound for the organic optoelectronic device represented by Chemical Formula 1 may be represented by any one of Chemical Formulas E-1 to E-5.

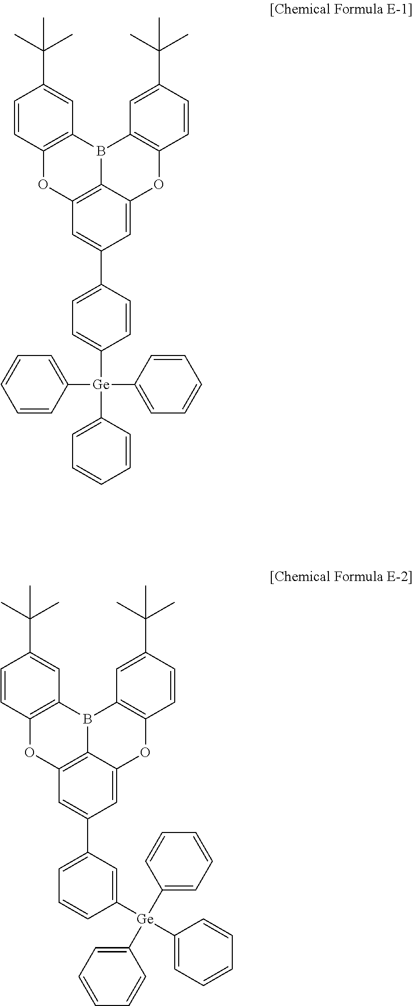

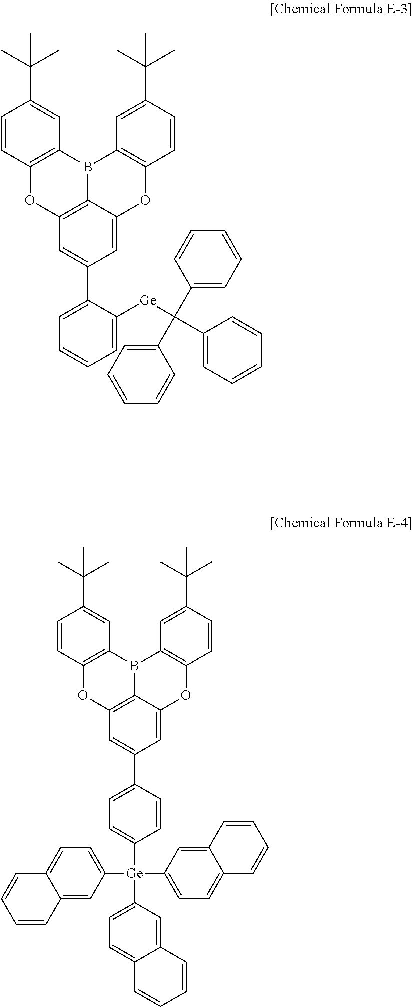

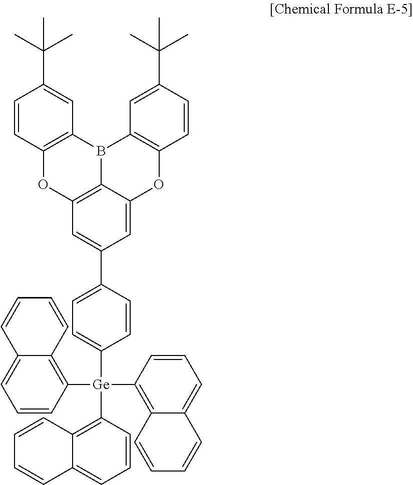

According to another embodiment, an optoelectronic device includes a first electrode and a second electrode facing each other, and an organic layer between the first electrode and the second electrode, wherein the organic layer includes the compound for the organic optoelectronic device.

The organic layer may include a hole transport layer, a light emitting layer, and an electron transport layer, wherein the hole transport layer may be disposed between the first electrode and the light emitting layer, the light emitting layer may be disposed between the hole transport layer and the electron transport layer, and the electron transport layer may be disposed between the light emitting layer and the second electrode.

The organic layer may include a hole transport layer, a light emitting layer, and an electron transport layer, wherein the hole transport layer may be disposed between the first electrode and the light emitting layer, the light emitting layer may be disposed between the hole transport layer and the electron transport layer, and the electron transport layer may be disposed between the light emitting layer and the second electrode. The hole transport layer may include a first hole transport layer, a second hole transport layer, and a third hole transport layer, wherein the first hole transport layer may be disposed between the first electrode and the second hole transport layer, the second hole transport layer may be disposed between the first hole transport layer and the third hole transport layer, and the third hole transport layer may be disposed between the second hole transport layer and the light emitting layer.

The compound may be included in the light emitting layer.

The compound may be a blue host material.

The optoelectronic device has excellent current efficiency, power efficiency, and external quantum efficiency.

### BRIEF DESCRIPTION OF THE DRAWINGS

FIGS. 1 and 2 are each independently cross-sectional views schematically illustrating configurations of optoelectronic devices according to embodiments.

FIGS. 3 to 6 are graphs showing optical and electrical characteristics of the organic optoelectronic devices according to Example 1, Comparative Example 1, and Comparative Example 2, respectively.

### DETAILED DESCRIPTION OF THE EMBODIMENTS

Hereinafter, embodiments of the present invention are described in detail. However, these embodiments are exemplary, the present invention is not limited thereto and the present invention is defined by the scope of claims.

As used herein, when a definition is not otherwise provided, “substituted” refers to replacement of at least one hydrogen of a substituent or a compound by deuterium, NH₂, a C1 to C4 amine group, a nitro group, a C1 to C4 silyl group, a C1 to C4 alkyl group, a C1 to C4 alkylsilyl group, a C1 to C4 alkoxy group, a fluoro group, a C1 to C4 trifluoroalkyl group, or a cyano group.

As used herein, when a definition is not otherwise provided, “hetero” refers to one including one to four heteroatoms selected from N, O, S, Se, Te, Si, and P.

As used herein, when a definition is not otherwise provided, “aryl group” refers to a group including at least one hydrocarbon aromatic moiety, and may include a group in which all elements of the hydrocarbon aromatic moiety have p-orbitals which form conjugation, for example a phenyl group, a naphthyl group, and the like, a group in which two or more hydrocarbon aromatic moieties may be linked by a sigma bond, for example a biphenyl group, a terphenyl group, a quarterphenyl group, and the like, and a group in which two or more hydrocarbon aromatic moieties are fused directly or indirectly to provide a non-aromatic fused ring, for example a fluorenyl group and the like. The aryl group may include monocyclic, polycyclic, or fused polycyclic (i.e., rings that share adjacent pairs of carbon atoms) functional groups.

As used herein, when a definition is not otherwise provided, “heteroaryl group” is a ring containing at least one heteroatom selected from N, O, S, Se, Te, P, and Si instead of carbon (C). When the heteroaryl group is a fused ring, at least one of the rings constituting the heteroaryl group may have a heteroatom, and each ring may have a heteroatom.

As used herein, when a definition is not otherwise provided, “*” means a moiety linked to the same or different atom or chemical formula.

Hereinafter, a compound for an organic optoelectronic device according to an embodiment is described.

A compound for an organic optoelectronic device according to an embodiment is represented by Chemical Formula 1.

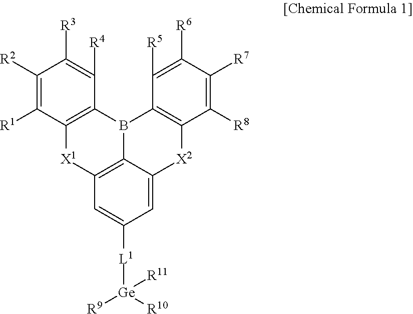

In Chemical Formula 1,

X¹ and X² are each independently an oxygen atom or a sulfur atom,

L¹ is a single bond, a substituted or unsubstituted C1 to C20 alkylene group, or a substituted or unsubstituted C6 to C20 arylene group, and

R¹ to R¹¹ are each independently a hydrogen atom, a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C20 aryl group, or a substituted or unsubstituted C2 to C20 heterocyclic group.

Among Korea's display business fields, organic optoelectronic devices (OLED) are one of the key future parts. In the OLED, an organic material emits light to show colors in red, green, and blue regions, but there is a problem in the blue region. The reason is that there is difficulty in charge injection due to a wide bandgap of the fundamental blue color, and accordingly, it is difficult to match an optimized device structure. In general, OLED light implements light in a host-dopant system, and energy transfer efficiency between the two is very important, but the energy transfer efficiency is very low in the case of blue host materials so far. Accordingly, the inventors of the present invention developed a host material for a new blue light emitting material including germanium atoms after numerous trials and errors, and when applied to a device, it has been confirmed that the electroluminescence (EL) performance is increased by about 15% compared to the existing one to complete the invention.

For example, X¹ and X² may each independently be an oxygen atom.

For example, L¹ may be a substituted or unsubstituted C6 to C20 arylene group, for example a phenylene group.

For example, the phenylene group may be represented by any one of Chemical Formulas L-1 to L-3.

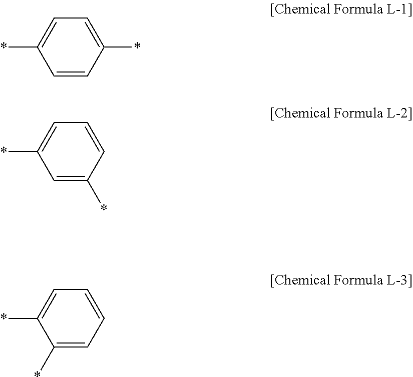 [SMILES: *c1ccc(*)cc1 ; *c1cccc(*)c1 ; *c1ccccc1*]

For example, at least one of R¹ to R⁴ may be a substituted or unsubstituted C1 to C20 alkyl group, and at least one or more of R⁵ to R⁸ may be a substituted or unsubstituted C1 to C20 alkyl group.

For example, R³ and R⁶ may each independently be a substituted or unsubstituted C1 to C20 alkyl group, for example, a C1 to C20 alkyl group substituted with a C1 to C10 alkyl group.

For example, R⁹ to R¹¹ may each independently be a substituted or unsubstituted C6 to C20 aryl group.

For example, R³ and R⁶ may each independently be a substituted or unsubstituted C1 to C20 alkyl group, R⁹ to R¹¹ may each independently be a substituted or unsubstituted C6 to C20 aryl group, and R¹, R², R⁴, R⁵, R⁷, and R⁸ may each independently be a hydrogen atom. In this case, energy transfer efficiency in the host-dopant system can be maximized.

For example, the compound for an organic optoelectronic device represented by Chemical Formula 1 may be represented by any one of Chemical Formulas E-1 to E-5, but is not necessarily limited thereto.

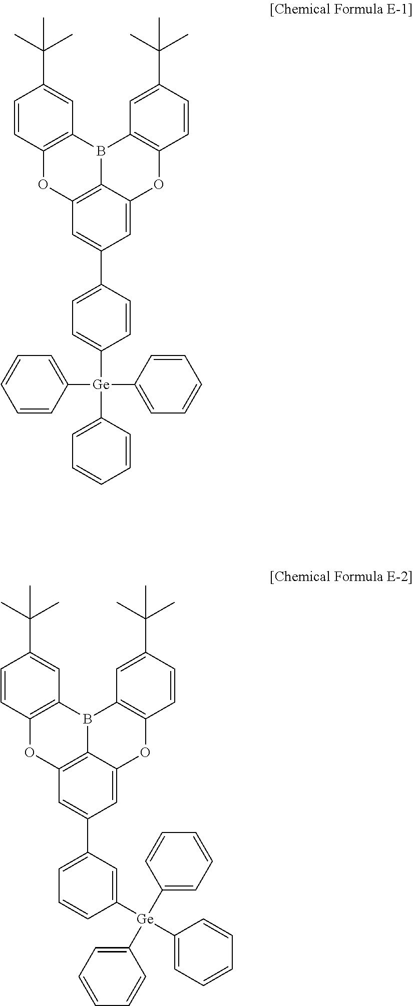

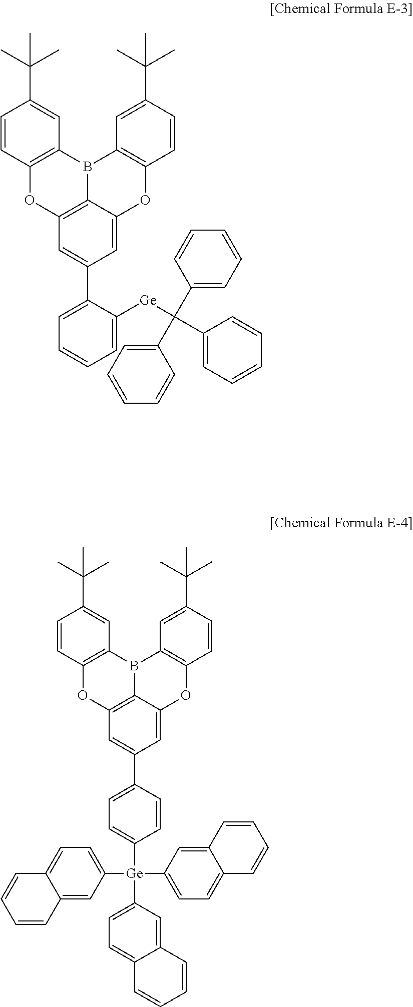

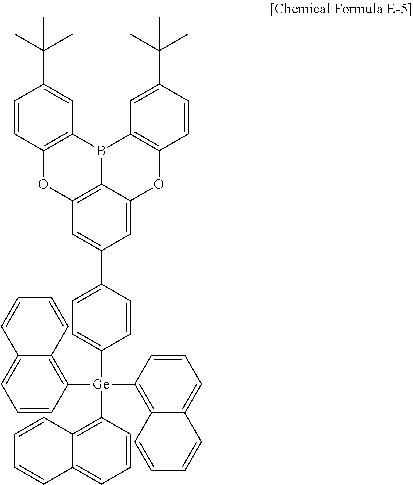

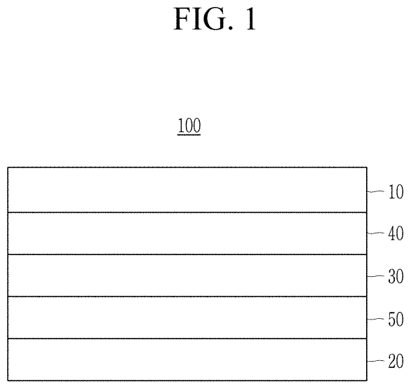

Hereinafter, an optoelectronic device according to an embodiment is described with reference to FIG. 1.

FIG. 1 is a cross-sectional view schematically illustrating a configuration of an optoelectronic device according to an embodiment.

Referring to FIG. 1, an optoelectronic device 100 according to an embodiment includes a first electrode 10 and a second electrode 20 facing each other, and an organic layer between the first electrode 10 and the second electrode 20. More specifically, the organic layer may include a hole transport layer 40, a light emitting layer 30, and an electron transport layer 50.

One of the first electrode 10 and the second electrode 20 may be a cathode and the other may be an anode.

At least one of the first electrode 10 and the second electrode 20 may be a transparent electrode. For example, when the first electrode 110 is a transparent electrode, bottom emission configured to emit light toward the first electrode 10 may be realized, and when the second electrode 20 is a transparent electrode, top emission configured to emit light toward the second electrode 20 may be realized. In addition, when both the first electrode 10 and the second electrode 20 are transparent electrodes, both surface emissions may be realized.

The light emitting layer 30 includes the compound represented by Chemical Formula 1. Chemical Formula 1 is the same as described above.

For example, the organic layer includes a hole transport layer, a light emitting layer, and an electron transport layer, wherein the hole transport layer is disposed between the first electrode and the light emitting layer, the light emitting layer is disposed between the hole transport layer and the electron transport layer, and the electron transport layer is disposed between the light emitting layer and the second electrode.

For example, the organic layer may include a hole transport layer, a light emitting layer, and an electron transport layer, wherein the hole transport layer may be disposed between the first electrode and the light emitting layer, the light emitting layer may be disposed between the hole transport layer and the electron transport layer, and the electron transport layer may be disposed between the light emitting layer and the second electrode, and the hole transport layer may include a first hole transport layer, a second hole transport layer, and a third hole transport layer, wherein the first hole transport layer may be disposed between the first electrode and the second hole transport layer, the second hole transport layer may be disposed between the first hole transport layer and the third hole transport layer, and the third hole transport layer may be disposed between the second hole transport layer and the light emitting layer.

For example, the compound represented by Chemical Formula 1 may be included in the light emitting layer. In this case, optical characteristics and electrical characteristics of the optoelectronic device according to the embodiment may be improved at the same time.

The light emitting layer may include the compound represented by Chemical Formula 1 as a blue host material, and may further include a dopant. Such a dopant may be a red, green, or blue dopant. The dopant is a material that causes light emission by being mixed in a small amount with a host (e.g., the compound represented by Chemical Formula 1), and is generally a material such as a metal complex that emits light by multiple excitation into a triplet or more. The dopant may be, for example, an inorganic, organic, or organic-inorganic compound, and may include one type or two or more types. The dopant may be included in an amount of about 0.1 wt % to about 20 wt % based on the total amount of the light emitting layer. An example of the dopant may include a phosphorescent dopant, and examples of the phosphorescent dopant may include an organometallic compound including Ir, Pt, Os, Ti, Zr, Hf, Eu, Tb, Tm, Fe, Co, Ni, Ru, Rh, Pd, or a combination thereof. The phosphorescent dopant my include, for example, a compound represented by Chemical Formula 8, but is not limited thereto.

L₂MX [Chemical Formula 8]

In Chemical Formula 8,

M is a metal, and L and X are the same as or different from each other and are ligands that form a complex with M.

M may be, for example, Ir, Pt, Os, Ti, Zr, Hf, Eu, Tb, Tm, Fe, Co, Ni, Ru, Rh, Pd, or a combination thereof, and L and X may be, for example, a bidentate ligand.

For example, the hole transport layer may include poly(9,9-dioctyl-fluorene-co-N-(4-butylphenyl)-diphenylamine), polyarylamine, poly(N-vinylcarbazole), poly(3,4-ethylenedioxythiophene), poly(3,4-ethylenedioxythiophene)polystyrene sulfonate, polyaniline, polypyrrole, N,N,N′,N′-tetrakis(4-methoxyphenyl)-benzidine, 4-bis[N-(1-naphthyl)-N-phenyl-amino]biphenyl, m-MTDATA, 4, 4′,4″-tris (N-carbazolyl)-triphenylamine, 1,1-bis (di-4-toylamino) phenylcyclohexane, a p-type metal oxide, a graphene oxide, or a combination thereof, but is not necessarily limited thereto.

The hole transport layer may be divided into a first hole transport layer and a second hole transport layer, wherein the first hole transport layer may be disposed between the first electrode and the second hole transport layer, and the second hole transport layer may be disposed between the first hole transport layer and the light emitting layer.

The hole transport layer 30 may further include at least one selected from poly(9,9-dioctyl-fluorene-co-N-(4-butylphenyl)-diphenylamine (TFB), polyarylamine, poly(N-vinylcarbazole), poly(3,4-ethylenedioxythiophene) (PEDOT), poly(3,4-ethylenedioxythiophene) polystyrene sulfonate (PEDOT:PSS), polyaniline, polypyrrole, N,N,N′,N′-tetrakis (4-methoxyphenyl)-benzidine (TPD), 4-bis[N-(1-naphthyl)-N-phenyl-amino]biphenyl (α-NPD), m-MTDATA (4,4′,4″-tris[phenyl(m-tolyl)amino]triphenylamine), 4,4′,4″-tris(N-carbazolyl)-triphenylamine (TCTA), 1,1-bis[(di-4-tolylamino)phenylcyclohexane (TAPC), a p-type metal oxide (e.g., NiO, WO₃, MoO₃, etc.), a carbon-based hole transport material such as graphene oxide, and a combination thereof, in addition to the aforementioned compounds.

The light emitting layer and the hole transport layer may be formed by coating a solution in which the aforementioned compound is dissolved in a solvent, inducing crosslinking by irradiating heat or light, and then drying and annealing the same.

The solution may be coated using spin coating, dipping, flow coating, or the like.

The optoelectronic device 100 may further include an electron transport layer between the second electrode 20 and the light emitting layer 30.

In addition, the optoelectronic device 100 may further include an electron injection layer and a hole injection layer for enhancing injection of electrons and holes.

The optoelectronic device is not particularly limited as long as it is a device capable of converting electrical energy and light energy, and examples thereof include a photoelectric device, a light emitting device, and a solar cell.

The aforementioned light emitting device may be applied to a light emitting display device.

Hereinafter, the embodiments are illustrated in more detail with reference to examples. These examples, however, are not in any sense to be interpreted as limiting the scope of the invention.

### Synthesis Example 1: Synthesis of Compound Represented by Chemical Formula E-1

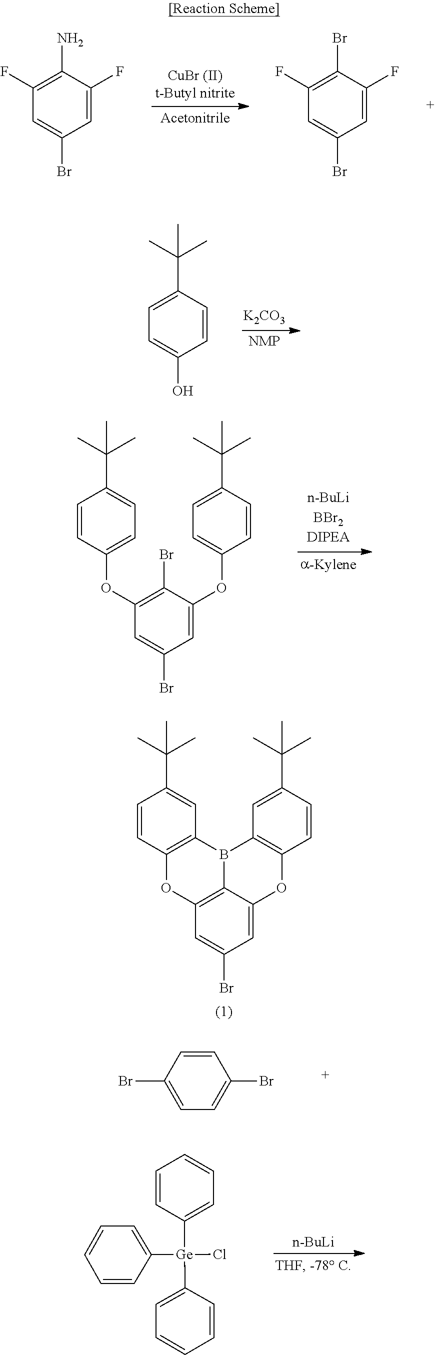

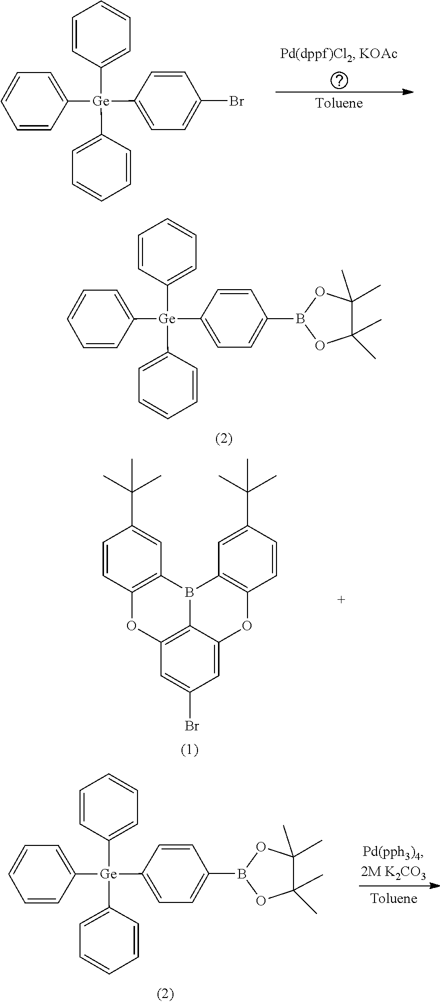

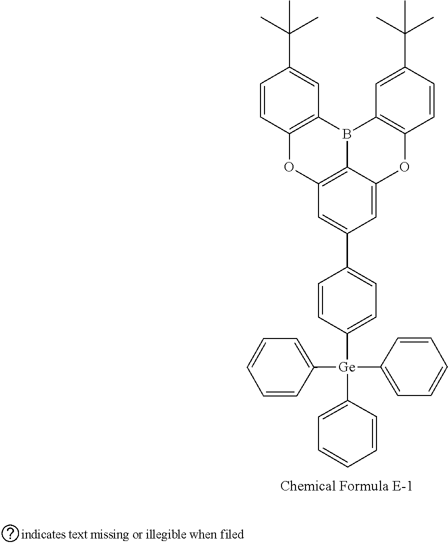

[Method for Preparing Chemical Formula E-1]

0.9 g (1.953 mmol) of Compound 1 of the above reaction scheme, 0.9 g (1.953 mmol) of Compound 2, and 0.09 g (0.078 mmol) of Pd(pph₃)₄ were put in a 3-neck round-bottom flask which was then substituted with nitrogen. 60 mL of anhydrous toluene was added thereto, and 15 mL of 2 M K₂CO₃ was added thereto and then stirred under reflux for 12 hours. When a reaction was completed, the resultant was treated for extraction with methylene chloride and DI water and then treated with MgSO₄ to remove moisture therefrom. A crude product therefrom was columned under a condition of EA:hexane=1:10, obtaining a compound represented by Chemical Formula E-1.

¹H-NMR (400 MHz, CDCl₃): δ 8.75 (d, 2H), 7.79-7.78 (d, 2H), 7.77-7.76 (d, 2H), 7.68-7.66 (d, 2H), 7.60-7.56 (m, 6H), 7.52-7.50 (d, 2H), 7.45 (s, 2H), 7.44-7.38 (m, 9H).7.83-7.72 (m, 4H), 7.64-7.62 (m, 3H), 7.56-7.44 (m, 12H), 1.51 (s, 18H) ppm.

### Comparative Synthesis Example 1: Synthesis of Compound Represented by Chemical Formula C-1

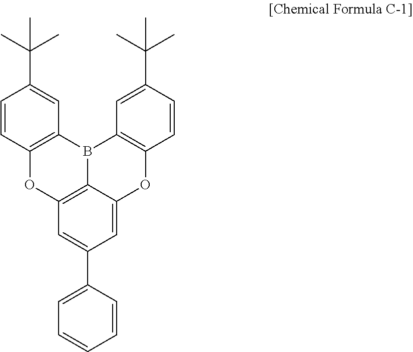 [SMILES: CC(C)(C)c1ccc2c(c1)B1c3cc(C(C)(C)C)ccc3Oc3cc(-c4ccccc4)cc(c31)O2]

0.9 g (1.953 mmol) of Compound 1 of the above reaction scheme, 0.26 g (1.953 mmol) of phenylboronic acid, and 0.09 g (0.078 mmol) of Pd(pph₃)₄ were put in a 3-neck round-bottom flask which was then substituted with nitrogen. After adding x mL of anhydrous toluene thereto and then adding y mL of 2 M K₂CO₃ thereto, the obtained mixture was stirred under reflux for 12 hours. When a reaction was completed, the resultant was treated for extraction with methylene chloride and DI water and then, with MgSO₄ to remove moisture. A crude product obtained therefrom was columned under the condition of EA:hexane=1:10, obtaining a compound represented by Chemical Formula C-1.

¹H-NMR (400 MHz, CDCl₃): b 8.76 (d, 2H), 7.79-7.75 (t, 4H), 7.52-7.49 (m, 4H), 7.44 (s, 2H), 1.49 (s, 18H) ppm.

### Comparative Synthesis Example 2: Synthesis of Compound Represented by Chemical Formula C-2

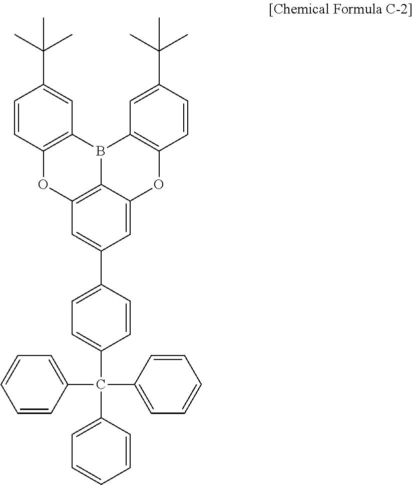 [SMILES: CC(C)(C)c1ccc2c(c1)B1c3cc(C(C)(C)C)ccc3Oc3cc(-c4ccc(C(c5ccccc5)(c5ccccc5)c5ccccc5)cc4)cc(c31)O2]

0.9 g (1.953 mmol) of Compound 1 of the above reaction scheme, 0.87 g (1.953 mmol) of 4,4,5,5-tetramethyl-2-(4-tritylphenyl)-1,3,2-dioxaborolane, and 0.09 g (0.078 mmol) of Pd(pph₃)₄ were put in a 3-neck round-bottom flask which was then substituted with nitrogen. After adding 60 mL of anhydrous toluene thereto and then adding 15 mL of 2 M K₂CO₃ thereto, the obtained mixture was stirred under reflux for 12 hours. When a reaction was completed, the resultant was treated for extraction with methylene chloride and DI water and then treated with MgSO₄ to remove moisture therefrom. A crude product obtained therefrom was columned under the condition of EA:hexane=1:10, obtaining a compound represented by Chemical Formula C-2.

¹H-NMR (400 MHz, CDCl₃): b 8.76 (d, 2H), 7.79-7.76 (d, 4H), 7.71-7.70 (d, 2H), 7.63-7.61 (d, 6H), 7.52-7.50 (d, 2H), 7.48-7.25 (m, 11H), 1.49 (s, 18H) ppm.

(Manufacture of Optoelectronic Devices)

### Example 1

A glass substrate coated with ITO (indium tin oxide) as a 1500 A-thick thin film was ultrasonic wave-washed with distilled water. After washing with the distilled water, the glass substrate was ultrasonic wave-washed with a solvent such as isopropyl alcohol, acetone, methanol, and the like and dried, and then moved to a plasma cleaner, cleaned by using oxygen plasma for 10 minutes, and moved to a vacuum depositor. After adjusting the internal conditions of the vacuum evaporator to less than 10⁵ torr by using a power pump, a first hole transport layer (HTL) was formed by depositing NPB to be 40 nm thick. On the first hole transport layer (HTL), a second hole transport layer (HTL) was formed by vacuum-depositing TCTA to be 15 nm thick. On the second hole transport layer (HTL), a third hole transport layer (HTL) was subsequently formed by vacuum-depositing mCP to be 15 nm thick. On the third hole transport layer (HTL), a light emitting layer was formed by using a compound represented by Chemical Formula E-1 as a host and a compound represented by Chemical Formula F-1 as a dopant. Herein, the doping was performed at a concentration of “98% Chemical Formula E-1 to 2% Chemical Formula F-1,” and the deposition was performed to have a thickness of 20 nm. Subsequently, on the light emitting layer, a 40 nm-thick electron transport layer (ETL) was formed by vacuum-depositing TmPyPB, and on the electron transport layer (ETL), a cathode was formed by sequentially vacuum-depositing LiF to be 1 nm thick and Al to be 200 nm thick, manufacturing an optoelectronic device.

A structure of the optoelectronic device is specifically as follows.

ITO/NPB (40 nm)/TCTA (15 nm)/mCP (15 nm)/Chemical Formula E-1 (host): 2% Chemical Formula F-1 (dopant) (20 nm)/TmPyPB (40 nm)/LiF (1 nm)/AI (200 nm)

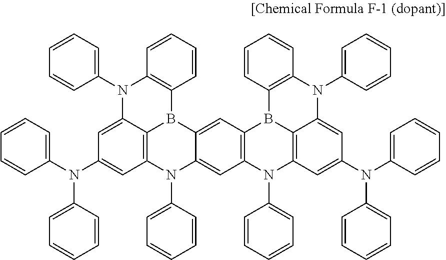 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

### Comparative Example 1

An optoelectronic device was manufactured in the same manner as in Example 1, except that the compound of Chemical Formula C-1 was used instead of the compound represented by Chemical Formula E-1.

### Comparative Example 2

An optoelectronic device was manufactured in the same manner as in Example 1, except that the compound of Chemical Formula C-2 was used instead of the compound represented by Chemical Formula E-1.

Evaluation:

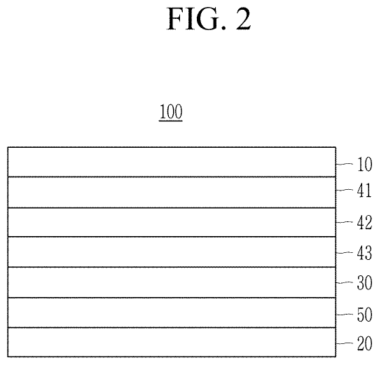

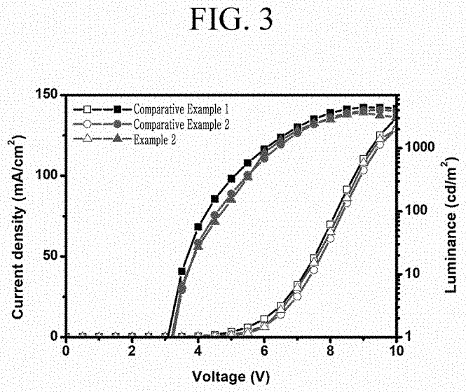

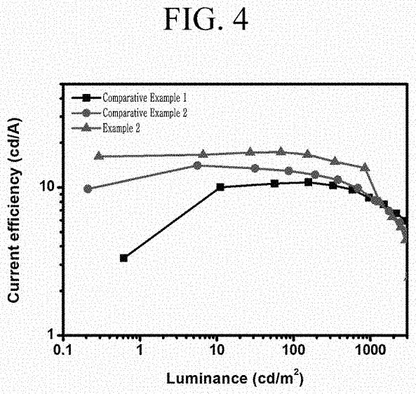

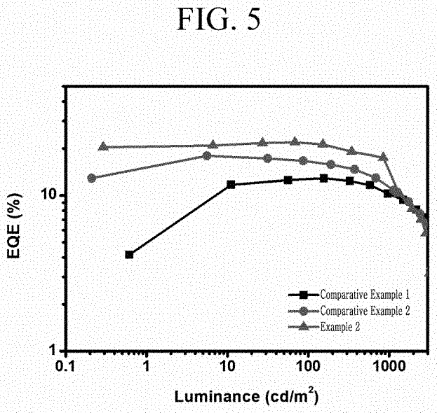

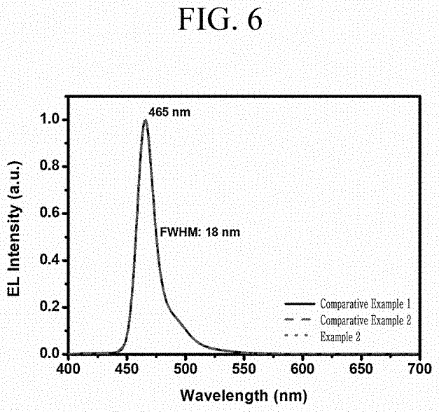

The optoelectronic devices according to Example 1 and Comparative Examples 1 and 2 were evaluated with respect to optical characteristics and electrical characteristics, which are shown in Table 1 and FIGS. 2 to 5.

TABLE 1

| | | Current | | | | | | | |
|---|---|---|---|---|---|---|---|---|---|
| | | efficiency (cd/A) | | | EQE (%) | | | | |
| | Tₒₙ | | 500 | 1,000 | | 500 | 1000 | ELₘₐₓ | CIE |
| | (V) | Max | nit | nit | Max | nit | nit | (nm) | (x, y) |
| Comp. Ex. 1 | 3.10 | 10.82 | 9.89 | 8.55 | 12.89 | 11.81 | 10.28 | 465 | (0.128, 0.089) |
| Comp. Ex. 2 | 3.23 | 14.05 | 10.61 | 8.67 | 17.95 | 13.95 | 11.33 | 465 | (0.128, 0.089) |
| Ex. 1 | 3.20 | 17.28 | 14.42 | 11.31 | 21.96 | 18.41 | 14.34 | 465 | (0.128, 0.089) |

Referring to Table 1 and FIGS. 2 to 5, the optoelectronic device according to an embodiment simultaneously exhibited excellent optical characteristics and electrical characteristics, compared with the optoelectronic device according to Comparative Example 1.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be examples but not limiting the present invention in any way.

### DESCRIPTION OF SYMBOLS

100: optoelectronic device
10: first electrode
20: second electrode
30: light emitting layer
40: hole transport layer
41: first hole transport layer
42: second hole transport layer
43: third hole transport layer
50: electron transport layer

What is claimed is:

1. A compound for an organic optoelectronic device represented by Chemical Formula 1: 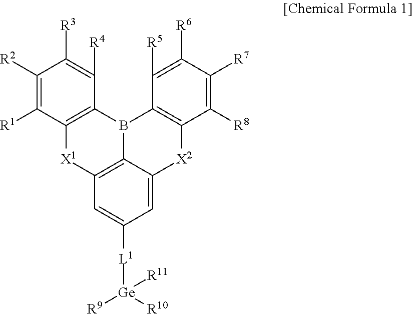
wherein, in Chemical Formula 1,
X¹ and X² are each independently an oxygen atom or a sulfur atom,
L¹ is a single bond, a substituted or unsubstituted C1 to C20 alkylene group, or a substituted or unsubstituted C6 to C20 arylene group, and
R¹ to R¹¹ are each independently a hydrogen atom, a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C20 aryl group, or a substituted or unsubstituted C2 to C20 heterocyclic group.

2. The compound of claim 1, wherein
X¹ and X² are each independently an oxygen atom.

3. The compound of claim 1, wherein
L¹ is a substituted or unsubstituted C6 to C20 arylene group.

4. The compound of claim 1, wherein
at least one of R¹ to R⁴ is a substituted or unsubstituted C1 to C20 alkyl group, and
at least one of R⁵ to R⁸ is a substituted or unsubstituted C1 to C20 alkyl group.

5. The compound of claim 1, wherein
R⁹ to R¹¹ are each independently a substituted or unsubstituted C6 to C20 aryl group.

6. The compound of claim 1, wherein
the compound represented by Chemical Formula 1 for the organic optoelectronic device is represented by any one of Chemical Formulas E-1 to E-5:

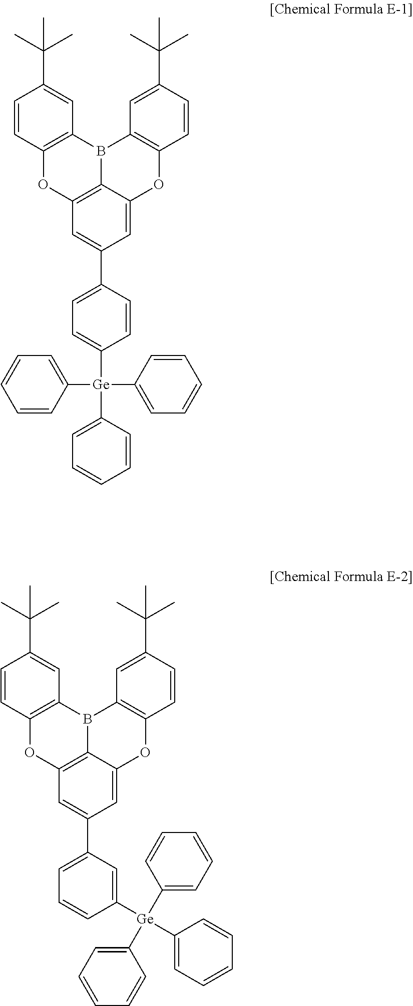

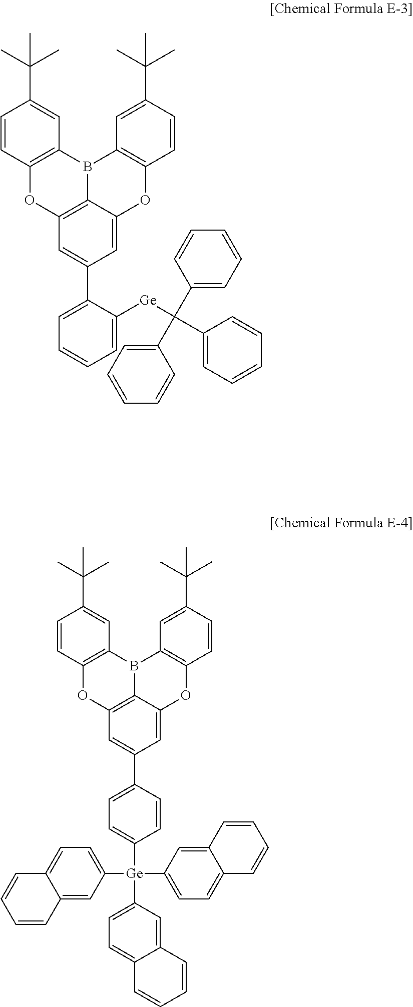

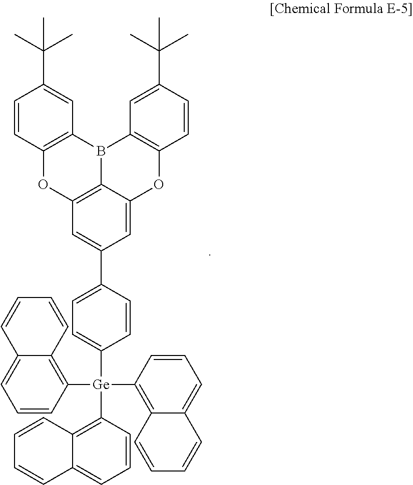

7. An optoelectronic device, comprising
a first electrode and a second electrode facing each other, and
an organic layer between the first electrode and the second electrode,
wherein the organic layer includes the compound of claim 1.

8. The optoelectronic device of claim 7, wherein
the organic layer includes a hole transport layer, a light emitting layer, and an electron transport layer,
wherein the hole transport layer is disposed between the first electrode and the light emitting layer,
the light emitting layer is disposed between the hole transport layer and the electron transport layer, and
the electron transport layer is disposed between the light emitting layer and the second electrode.

9. The optoelectronic device of claim 7, wherein
the organic layer includes a hole transport layer, a light emitting layer, and an electron transport layer,
wherein the hole transport layer is disposed between the first electrode and the light emitting layer,
the light emitting layer is disposed between the hole transport layer and the electron transport layer,
the electron transport layer is disposed between the light emitting layer and the second electrode, and
the hole transport layer includes a first hole transport layer, a second hole transport layer, and a third hole transport layer,
wherein the first hole transport layer is disposed between the first electrode and the second hole transport layer,
the second hole transport layer is disposed between the first hole transport layer and the third hole transport layer, and
the third hole transport layer is disposed between the second hole transport layer and the light emitting layer.

10. The optoelectronic device of claim 7, wherein
the compound is included in the light emitting layer.

11. The optoelectronic device of claim 10, wherein
the compound is a blue host material.
